(19) United States
(12) Patent Application Publication
(10) Pub. No.: US 2015/0129946 A1
(43) Pub. Date: May 14, 2015

(54) SELF REFERENCE THERMALLY ASSISTED MRAM WITH LOW MOMENT FERROMAGNET STORAGE LAYER

(71) Applicants: International Business Machines Corporation, Armonk, NY (US); Crocus Technology, SA, Grenoble Cedex (FR)

(72) Inventors: Anthony J. Annunziata, Stamford, CT (US); Sebastien Bandiera, Grenoble (FR); Lucien Lombard, Grenoble (FR); Lucian Prejbeanu, Grenoble (FR); Philip L. Trouilloud, Norwood, NJ (US); Daniel C. Worledge, Cortlandt Manor, NY (US)

(21) Appl. No.: 14/499,523

(22) Filed: Sep. 29, 2014

Related U.S. Application Data
(60) Provisional application No. 61/903,600, filed on Nov. 13, 2013.
(60) Provisional application No. 61/903,598, filed on Nov. 13, 2013.

(51) Int. Cl. H01L 27/22; H01L 43/02

(52) U.S. Cl. CPC H01L 27/222; H01L 43/02
USPC 257/295

(57) ABSTRACT

A mechanism is provided for a thermally assisted magnetoresistive random access memory device (TAS-MRAM) with reduced power for reading and writing. A tunnel barrier is disposed adjacent to a ferromagnetic sense layer and a ferromagnetic storage layer, such that the tunnel barrier is sandwiched between the ferromagnetic sense layer and the ferromagnetic storage layer. An antiferromagnetic pinning layer is disposed adjacent to the ferromagnetic storage layer. The pinning layer pins a magnetic moment of the storage layer until heating is applied. The storage layer includes a non-magnetic material to reduce a storage layer magnetization as compared to not having the non-magnetic material. The sense layer includes the non-magnetic material to reduce a sense layer magnetization as compared to not having the non-magnetic material. A reduction in the storage layer magnetization and sense layer magnetization reduces the magnetostatic interaction between the storage layer and sense layer, resulting in less read/write power.

### DOMESTIC PRIORITY

This application claims priority to U.S. Provisional Application Ser. No. 61/903,598, entitled “SELF REFERENCE THERMALLY ASSISTED MRAM WITH LOW MOMENT STORAGE LAYER”, filed Nov. 13, 2013, and claims priority to U.S. Provisional Application Ser. No. 61/903,600, entitled “SELF REFERENCE THERMALLY ASSISTED MRAM WITH LOW MOMENT SYNTHETIC ANTIFERROMAGNET STORAGE LAYER”, filed Nov. 13, 2013, both of which are incorporated herein by reference in their entirety.

### BACKGROUND

The present invention relates generally to magnetic memory devices, and more specifically, to thermally assisted MRAM devices that provide low moment ferromagnet storage and sense layers.

Magnetoresistive random access memory (MRAM) is a non-volatile computer memory (NVRAM) technology. Unlike conventional RAM chip technologies, MRAM data is not stored as electric charge or current flows, but by magnetic storage elements. The elements are formed from two ferromagnetic plates, each of which can hold a magnetic moment, separated by a thin insulating layer. One of the two plates is a reference magnet set to a particular polarity; the other plate's field can be changed to match that of an external field to store memory and is termed the “free magnet” or “free-layer”. This configuration is known as a magnetic tunnel junction and is the simplest structure for a MRAM bit. A memory device is built from a grid of such “cells.” In some configurations of MRAM, such as the type further discussed herein, both the reference and free layers of the magnetic tunnel junctions can be switched using an external magnetic field.

### SUMMARY

According to one embodiment, a thermally assisted magnetoresistive random access memory device (TAS-MRAM) with reduced power for reading and writing is provided. The device includes a tunnel barrier disposed adjacent to a ferromagnetic sense layer and a ferromagnetic storage layer, such that the tunnel barrier is sandwiched between the ferromagnetic sense layer and the ferromagnetic storage layer. The ferromagnetic sense layer, the tunnel barrier, and the ferromagnetic storage layer together form a magnetic tunnel junction. An antiferromagnetic pinning layer is disposed adjacent to the ferromagnetic storage layer. The antiferromagnetic pinning layer pins a magnetic moment of the ferromagnetic storage layer until heating is applied. The ferromagnetic storage layer includes a non-magnetic material to reduce a storage layer magnetization of the ferromagnetic storage layer as compared to not having the non-magnetic material, and/or the ferromagnetic sense layer includes the non-magnetic material to reduce a sense layer magnetization of the ferromagnetic sense layer as compared to not having the non-magnetic material. A reduction at least one of in the storage layer magnetization of the ferromagnetic storage layer and in the sense layer magnetization of the ferromagnetic sense layer reduces the magnetostatic interaction between the ferromagnetic storage layer and the ferromagnetic sense layer, resulting in less power to read and write to the magnetic tunnel junction as compared to the ferromagnetic storage layer and the ferromagnetic sense layer not having the non-magnetic material.

According to another embodiment, a thermally assisted magnetoresistive random access memory device (TAS-MRAM) with reduced power for reading and writing is provided. The device includes a tunnel barrier disposed adjacent to a ferromagnetic sense layer and a synthetic antiferromagnet storage layer, such that the tunnel barrier is sandwiched between the ferromagnetic sense layer and the synthetic antiferromagnet storage layer. The synthetic antiferromagnet storage layer includes a first ferromagnetic storage layer disposed adjacent to the tunnel barrier, and a non-magnetic coupling layer sandwiched between the first ferromagnetic storage layer and a second ferromagnetic storage layer. An antiferromagnetic pinning layer is disposed adjacent to the second ferromagnetic storage layer of the synthetic antiferromagnet storage layer but opposite the non-magnetic coupling layer. A non-magnetic material included at least one of in the first ferromagnetic storage layer, in the second ferromagnetic storage layer, and in the ferromagnetic sense layer. The non-magnetic material reduces a first storage layer magnetization of the first ferromagnetic storage layer, reduces a second storage layer magnetization of the second ferromagnetic storage layer, and reduces a sense layer magnetization of the ferromagnetic sense layer as respectively compared to not having the non-magnetic material. A reduction in the first storage layer magnetization, the second storage layer magnetization, and the sense layer magnetization reduces magnetostatic interaction dispersions between the first ferromagnetic storage layer, the second ferromagnetic storage layer, and the ferromagnetic sense layer, resulting in less power to read and write as compared to the first ferromagnetic storage layer, the second ferromagnetic storage layer, and the ferromagnetic sense layer not having the non-magnetic material. The reduced magnetization permits a greater thickness for the first ferromagnetic storage layer, the second ferromagnetic storage layer, and the ferromagnetic sense layer as compared to not having the non-magnetic material.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a cross-sectional view of a thermally-assisted magnetoresistive random access memory (TAS-MRAM) device according to an embodiment.

FIG. 2A illustrates a reading procedure of a self-referenced stack when the sense layer is switched in one direction according to an embodiment.

FIG. 2B illustrates the reading procedure of the self-referenced stack when the sense layer is switched in the other direction according to an embodiment.

FIG. 3A is a schematic diagram illustrating depositing an alloy by sputtering from a composite target A plus B made of the desired alloy to form a storage layer and/or sense layer with reduced magnetization according to an embodiment.

FIG. 3B is a schematic diagram illustrating depositing the alloy by co-sputtering from different targets A and B containing the desired magnetic and non-magnetic elements to form the storage layer and/or sense layer with reduced magnetization according to an embodiment.

FIG. 3C is a schematic diagram illustrating a multilayered stack comprising ferromagnetic and non-magnetic bilayers with multiple repetitions to form the storage layer and/or sense layer with reduced magnetization according to an embodiment.

FIG. 4A is a chart illustrating the reduction of magnetization (Mₛ) for the storage layer and/or sense layer using various non-magnetic dopant materials according to an embodiment.

FIG. 4B is a chart illustrating a reduction in stray fields (H_{bias}) generated by the storage layer on sense layer which is by the reduction in magnetization from the various non-magnetic dopant materials according to an embodiment.

FIG. 5 is a flow diagram illustrating a method of forming the thermally assisted magnetoresistive random access memory with device reduced power for reading and writing according to an embodiment.

FIG. 6 is a cross-sectional view of a thermally-assisted magnetoresistive random access memory (TAS-MRAM) device according to an embodiment.

FIG. 7A illustrates a reading procedure of a self-referenced stack when the sense layer is switched in one direction according to an embodiment.

FIG. 7B illustrates the reading procedure of the self-referenced stack when the sense layer is switched in the other direction according to an embodiment.

FIG. 8A is a schematic diagram illustrating depositing an alloy by sputtering from a composite target A and B made of the desired alloy to form a storage layer and/or sense layer with reduced magnetization according to an embodiment.

FIG. 8B is a schematic diagram illustrating depositing the alloy by co-sputtering from different targets A and B containing the desired magnetic and non-magnetic elements to form the storage layer and/or sense layer with reduced magnetization according to an embodiment.

FIG. 8C is a schematic diagram illustrating a multilayered stack comprising ferromagnetic and non-magnetic bilayers with multiple repetitions to form the storage layer and/or sense layer with reduced magnetization according to an embodiment.

FIGS. 9A and 9B together is a flow diagram illustrating a method of forming the thermally assisted magnetoresistive random access memory device with reduced power for reading and writing according to an embodiment.

FIG. 10 is a block diagram illustrating an example of a computer which can be connected to, operate, and/or include the MRAM device(s) according to an embodiment.

### DETAILED DESCRIPTION

Thermally-assisted magnetoresistive random access memory (TAS-MRAM) requires heating of the magnetic tunnel junction stack to a write temperature (T_{write}) higher than the operating temperature (Tₒₚ) in order to write the device. This is typically done by heating from a bias current that is applied on the magnetic tunnel junction during the write process. The amount of power required to heat the device to T_{write} is strongly dependent on the thermal conductivity between the device and the surrounding structures and substrate, which are at Tₒₚ<T_{write}.

In particular, the TAS-MRAM cell is composed of a magnetic tunnel junction with an antiferromagnetic (AF) pinning layer. This AF layer must be heated to T_{w}>Tₒₚ in order to allow writing data to (i.e., switch the magnetic moment) the storage layer (SL) of the TAS-MRAM device. Embodiments described herein reduce the power required to switch the magnetic moment in the storage layer and the sense layer (also referred to as a reference layer).

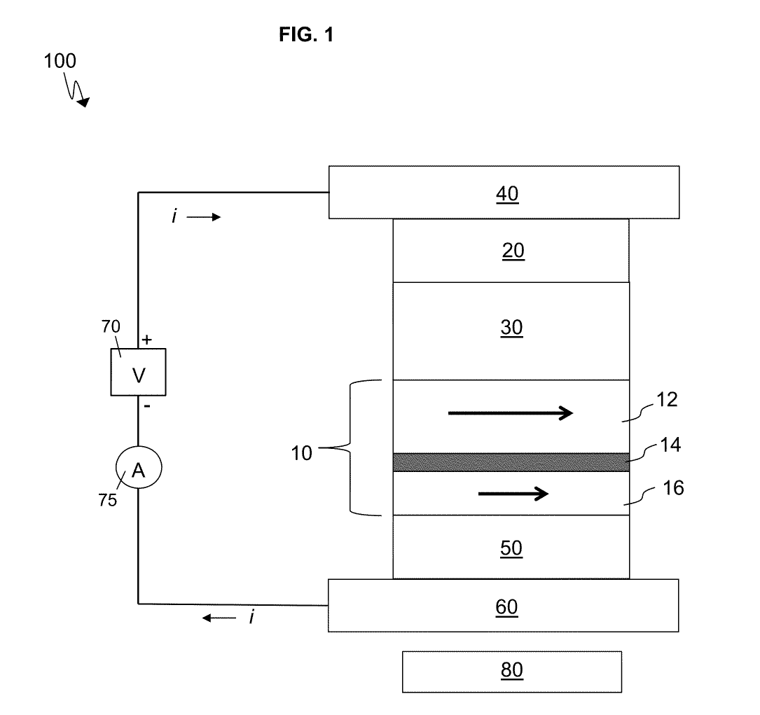

Now turning to the figures, FIG. 1 illustrates a structure for a thermally-assisted magnetoresistive random access memory (TAS-MRAM) device 100 according to an embodiment. FIG. 1 depicts a cross-sectional view of the device 100.

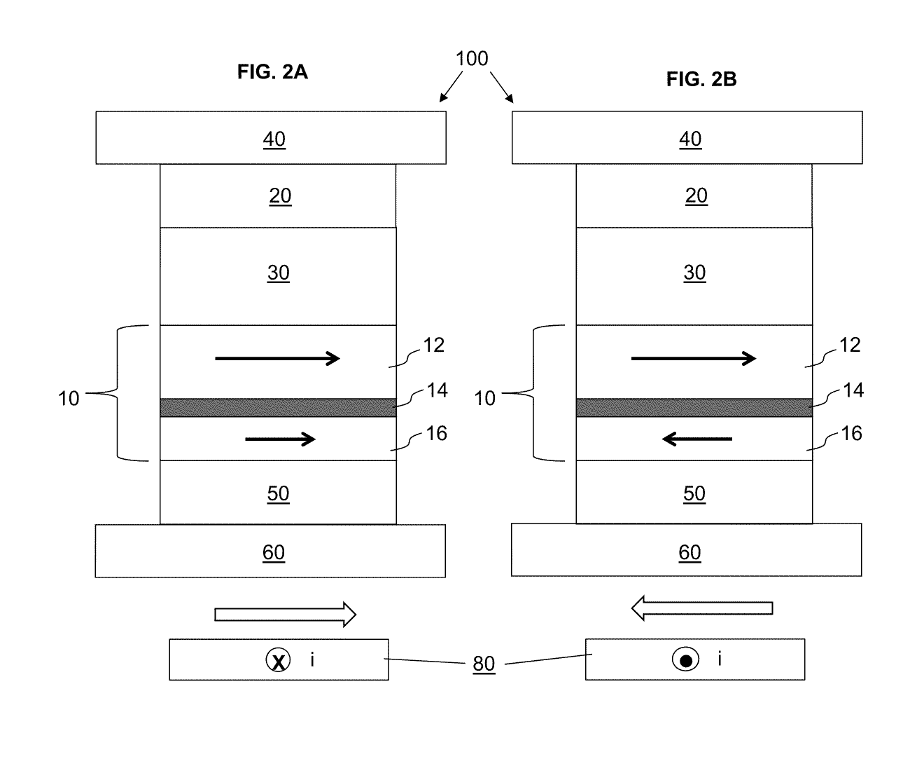

The structure of the MRAM device 100 includes a magnetic tunnel junction (MTJ) 10. The magnetic tunnel junction 10 may include a ferromagnetic sense layer 16 with a non-magnetic tunnel barrier 14 disposed at an interface of the ferromagnetic sense layer 16. The magnetic tunnel junction 10 also includes a storage layer 12 disposed at an interface of the non-magnetic tunnel barrier 14. The non-magnetic tunnel barrier 14 may be a semiconductor or insulator. The storage layer 12 includes ferromagnetic material as discussed further herein. Although not shown in FIG. 1 (FIG. 2), the reverse configuration is also contemplated for the magnetic tunnel junction 10 in which the sense layer is deposited on top of the tunnel barrier, and tunnel barrier is deposited on top of the storage layer.

An antiferromagnetic (AF) pinning layer 30 is disposed at an interface of the storage layer 12. Note that in the reverse configuration the storage layer 12 can be disposed on top of the antiferromagnetic (AF) pinning layer 30. The antiferromagnetic pinning layer 30 is an antiferromagnet and may include materials such as, e.g., IrMn, FeMn, PtMn, etc. The antiferromagnetic pinning layer 30 is composed of two magnetic sublattices. The two magnetic sublattices have opposite magnetic orientations (also referred to as magnetic moments), such that the net magnetic moment of the antiferromagnetic pinning layer 30 is zero. Since antiferromagnets have a small or no net magnetization, their spin orientation is only negligibly influenced by an externally applied magnetic field.

A contact structure 20 is disposed on top of the antiferromagnetic pinning layer 30 connecting the magnetic tunnel junction 10 (MRAM device 100) to a first wire 40. The contact structure 20 may also be refereed to as a non-magnetic cap. In the case of a reverse structure, the antiferromagnet is deposited on the top of the seed layer.

The magnetic tunnel junction 10 (particularly the ferromagnetic sense layer 16) is disposed on top of a seed layer 50. However, in the case of a reverse structure, the antiferromagnet is deposited on the top of the seed layer. In FIG. 1, the seed layer 50 is the seed for growing the ferromagnetic sense layer 16. Note that the seed layer 50 is optional, and in one implementation, the seed layer 50 may not be present. The seed layer 50, when present, is disposed on top of a second wire 60. When the seed layer 50 is not present, the ferromagnetic sense layer 16 is disposed on top of the second wire 60. The seed layer 50 is disposed on and/or connected to the second wire 60. The wires 40 and 60 connect the MRAM device 100 to a voltage source 70 (for generating the write bias current to heat the MRAM device 100) and ammeter 75 for measuring current. As such, the resistance of the MTJ 10 (i.e., MRAM device 100) can be determined.

The magnetic tunnel junction 10 comprises a tunnel barrier sandwiched by two ferromagnetic layers that can be used to store binary data. Indeed, the resistance of the magnetic tunnel junction 10 depends on the magnetic configuration (low resistance for parallel magnetizations, and high resistance for antiparallel magnetizations). The relative difference of resistance is called tunnel magnetoresistance (TMR). Due to the hysteresis of the ferromagnetic layers (i.e., the storage layer 12 and ferromagnetic sense layer 16), the magnetic tunnel junction 10 is used as a non-volatile cell. One ferromagnetic layer presents high anisotropy, and cannot be switched under the functioning conditions of the device. This layer is called the reference layer. The other ferromagnetic layer (i.e., the storage layer 12) is stable under the stand-by conditions, but can be switched by a combination of write magnetic field along with a write current sent through the junction.

In one reading scheme that improves the read margin of magnetic tunnel junction 10, the ferromagnetic sense layer 16 replaces the reference layer. FIGS. 2A and 2B (generally referred to as FIG. 2) illustrate a reading procedure of the self-referenced magnetic tunnel junction 10 in the thermally-assisted magnetoresistive random access memory (TAS-MRAM) device 100 according to an embodiment.

During reading in FIG. 2A, the magnetic moment (shown by the solid arrow pointing to the right) of the ferromagnetic sense layer 16 is switched in one direction via current i (the “x” indicates that the current i is entering the plane of the page) applied in a field line 80 to generate a magnetic field shown by an open arrow pointing to the right. Note that the magnetic moment of the storage layer 12 continues pointing to the right and does not flip even when the magnetic field is applied via the field line 80. This is because the write bias current is not applied by the voltage source 70 to de-pin (unpin) the storage layer 12 from the antiferromagnetic pinning layer 30.

While on the other hand in FIG. 2B, the magnetic moment (now shown by the solid arrow pointing to the left) of the ferromagnetic sense layer 16 is switched in the opposite direction via the current i (the dot “” indicates that the current i is exiting the plane of the page) applied in the field line 80 to generate the magnetic field shown by an open arrow pointing to the left.

The difference in resistance between the two reading steps (i.e., between the magnetic moments of the ferromagnetic sense layer 16 pointing to the right and then left) can be either positive or negative, depending on the direction of the magnetic moment of the storage layer 12. The sign of the resistance change yields the stored information in the storage layer 12. The storage layer 12 has an exchange bias pinned ferromagnetic layer that is pinned by the antiferromagnetic material of the antiferromagnetic pinning layer 30. The exchange bias acting on the storage layer 12 can be overcome (in order to write to the storage layer 12, i.e., flip its magnetic moment) by applying a current pulse (via the voltage source 70) through the stack (i.e., the MRAM device 100) that heats the junction (antiferromagnetic pinning layer 30) above its blocking temperature, in combination with the magnetic field (of the field line 80) that switches the now unpinned storage layer 12. The (magnetic moment) storage layer 12 recovers to its new pinning direction during cooling when the write bias current is stopped.

Unlike embodiments but in a conventional MRAM device, this kind of stack lacks scalability. Indeed, due to the magnetostatic interactions between the sense and the storage layers, the sense layer reversal is biased. This shift increases when the pillar diameter decreases (width), so that the magnetic field required to switch the sense layer during reading becomes too high compared to the magnetic field that can be generated by field lines. Using standard materials, it is not possible to scale the magnetic tunnel junction diameter (width) below 250 nanometer (nm).

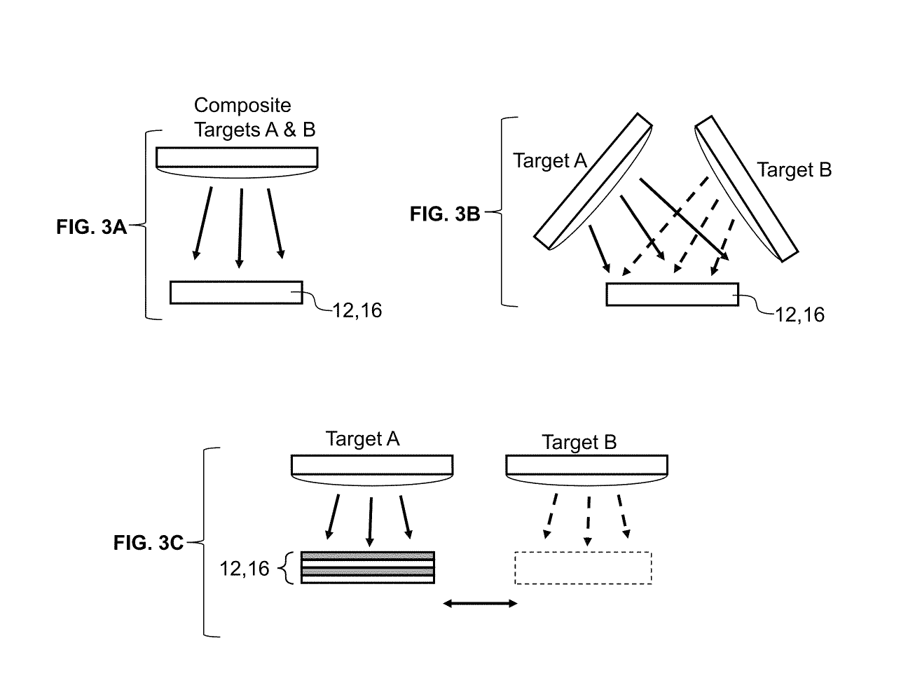

However, embodiments are able to scale the diameter of the magnetic tunnel junction 10 (including layers 20, 30, and 50) below 250 nm and further below 100 nm (in diameter) by reducing the magnetization of the storage layer 12 and the ferromagnetic sense layer 16. For example, the embodiments discussed herein address the problem of magnetostatic interactions between the ferromagnetic sense layer 16 and the storage layer 12 by using low magnetization ferromagnetic layers. Using low magnetization ferromagnetic layers in both the storage layer 12 and the ferromagnetic sense layer 16 reduces the strength/magnitude respectively of the magnetic moments (and stray fields) in the storage layer 12 and the ferromagnetic sense layer 16. By reducing the magnetic moment in the storage layer 12, the exchange bias field of the ferromagnetic sense layer 16 is reduced (which consequently reduces the required magnitude of the reading field (of the field line 80) that is needed). In order to reduce the magnitude of the writing field (of the field line 80), the magnetic moment of the ferromagnetic sense layer 16 and the magnetic moment in the ferromagnetic storage layer 12 are reduced which in turn reduces the magnetostatic interaction (of the layers 12 and 16) during the writing procedure. Reducing the magnetic moment of the ferromagnetic layers (i.e., the storage layer 12 and the ferromagnetic sense layer 16) is achieved by doping ferromagnetic materials with non-magnetic elements (discussed further in FIG. 3).

Embodiments use ferromagnetic layers doped with non-magnetic elements (i.e., in the storage layer 12 and/or in the ferromagnetic sense layer 16) in the self-referenced stack (of the thermally-assisted magnetoresistive random access memory (TAS-MRAM) device 100) that present a magnetization reduction as compared to the standard ferromagnetic materials that do not have the reduced magnetization for thermally-assisted magnetoresistive random access memory (TAS-MRAM) device.

To make the storage layer 12 and the ferromagnetic sense layer 16 with reduced magnetization (i.e., reduced magnetic moments in each), FIGS. 3A, 3B, and 3C (generally referred to as FIG. 3) illustrate doping the ferromagnetic layers of the storage layer 12 and the ferromagnetic sense layer 16 to according to an embodiment. Note that such a doped ferromagnetic layer can be made by sputtering from an alloyed target, by co-sputtering from several targets, and/or by making a multilayer that consists of alternating ferromagnetic and non-magnetic thin layers.

The doped ferromagnetic layers can be utilized in the ferromagnetic sense layer 16, the storage layer 12, or both. In order to reduce the magnetic moment of the sense or storage layer magnetization, non-magnetic materials can be used to dope the ferromagnetic layers. The ferromagnetic materials include a Co, Fe, and/or Ni based alloy, while the non-magnetic doping elements can be Ta, Ti, Hf, Cr, Nb, Mo, Zr, and/or any alloy containing one of these elements. The doped ferromagnetic layer of the storage layer 12 has a magnetization that is (typically) below 1000 emu/cm³, where emu is electromagnetic unit. The doped ferromagnetic layer of the ferromagnetic sense layer 16 also has a magnetization that is (typically) below 1000 emu/cm³. This reduced magnetization in both the storage layer 12 and ferromagnetic sense layer 16 reduces the magneto static interaction between the storage layer 12 and ferromagnetic sense layer 16 (i.e., the stray fields between layers 12 and 16), which means that less current in the field line 80 is needed to write (i.e., flip the magnetic moment of the storage layer 12) and read (i.e., flip the magnetic moment of the ferromagnetic sense layer 16) the device 100. As noted above, reducing magnetization in the layers 12 and 16 to reduce stray fields is what permits the diameter of the magnetic tunnel junction 10 (including layers 20, 30, and 50) to be below 250 nm and further below 100 nm.

The storage layer 12 is typically 1-2 nm (nanometer) thick, but the thickness of the storage layer 12 can be between 0.2 and 10 nm. The ferromagnetic sense layer 16 is typically 1-2 nm thick, but the thickness of the ferromagnetic sense layer 16 can be between 0.2 and 10 nm. However, when there is no doping of the ferromagnetic layer in the storage layer and ferromagnetic sense layer (i.e., their magnetization is not reduced), a conventional system has a storage layer with a conventional magnetization of 1000 to 1700 emu/cm³ and the sense layer has a conventional magnetization of 1000 to 1700 emu/cm³.

The storage layer 12 is pinned with a Mn based antiferromagnet in antiferromagnetic pinning layer 30, and the antiferromagnetic pinning layer 30 may be PtMn, IrMn, IrCrMn, and/or FeMn.

FIG. 3 illustrates three example techniques to deposit the doped ferromagnetic layers for the storage layer 12 and the ferromagnetic sense layer 16, which are part of the stack in the thermally-assisted magnetoresistive random access memory device 100 discussed herein. FIG. 3A shows depositing an alloy by sputtering from a composite target A plus B made of the desired alloy to form the desired storage layer 12 and/or ferromagnetic sense layer 16 with reduced magnetization. The material A is the ferromagnetic material (i.e., magnetic material discussed herein) and the material B is the non-magnetic material (discussed herein). The materials A and B have been made into an alloy in FIG. 3A for deposition to form the desired storage layer 12 and/or ferromagnetic sense layer 16.

FIG. 3B shows depositing the alloy by co-sputtering from different targets A and B containing the desired magnetic and non-magnetic elements to form the desired storage layer 12 and/or ferromagnetic sense layer 16 with reduced magnetization. The target A is the ferromagnetic material (i.e., magnetic material) and the target B is the non-magnetic material. The doped ferromagnetic layers of the storage layer 12 and/or ferromagnetic sense layer 16 respectively are formed by co-sputtering from the separate target A and separate target B.

FIG. 3C shows depositing a multilayered stack comprising ferromagnetic and non-magnetic bilayers with n repetitions, where n ranges from 1 to 20. Again, the target A is the ferromagnetic material (i.e., magnetic material) and the target B is the non-magnetic material. For example, sputtering from target A is performed to deposit a ferromagnetic layer on the storage layer 12/ferromagnetic sense layer 16, and then the storage layer 12/ferromagnetic sense layer 16 is shifted under the target B in order to perform sputtering from target B to deposit the non-magnetic layer on top of the previously deposited ferromagnetic layer (i.e., thus forming the first bilayer). Next, the storage layer 12/ferromagnetic sense layer 16 is shifted back under target A to deposit another ferromagnetic layer on top of the non-magnetic layer, and then the storage layer 12/ferromagnetic sense layer 16 is shifted under the target B in order to deposit the non-magnetic layer on top of the ferromagnetic layer. This process repeats for n repetitions. The thickness of each deposited ferromagnetic layer of the ferromagnetic material (FM) is between 0.1 to 2 nm while thickness of the non-magnetic material (NM) is below 1 nm.

In FIG. 3, the doped ferromagnetic layers (i.e., ferromagnetic layers doped with non-magnetic material) can present a gradient of doping. This gradient can be made by varying the sputtering conditions (pressure, flow, power, etc.) during the doped layer deposition, and/or by varying the relative thicknesses of ferromagnetic layer and non-magnetic material layer in the multilayer case. In the multilayer case, the multilayer stack comprises FM1/NM1/ . . . /FMn/NMn, where FMk and NMk denote ferromagnetic and non-magnetic materials of different nature and thickness.

The ferromagnetic layers' doping is designed to be compatible with these characteristics: TMR ratio above 10%, MTJ resistance-area product below 100 Ohm·μm², and exchange bias field of the storage layer above 200 Oe at room temperature.

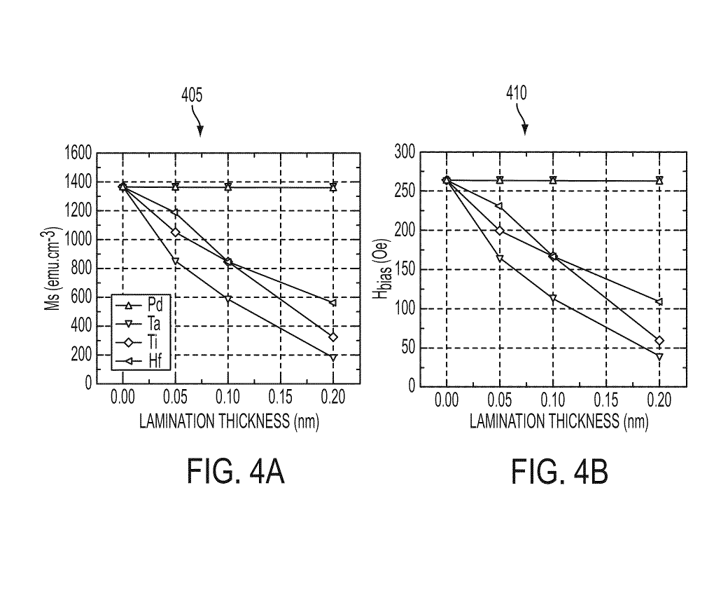

FIG. 4A is a chart 405 illustrating the reduction of magnetization (Mₛ) for the storage layer and/or sense layer using various non-magnetic dopant materials according to an embodiment. With reference to FIGS. 4A and 4B, the doping is accomplished by multilayering (as shown in FIG. 3C). The chart 405 shows the magnetization saturation, Mₛ, (emu/cm³) on the y-axis. On the x-axis, the chart 405 shows the lamination thickness (nm) of each non-magnetic layer in the multilayer storage layer 12. As can be seen, as the lamination thickness of each non-magnetic layer increases (which is similar to increasing the percentage of non-magnetic material in the storage layer 12 as compared to the ferromagnetic material), the magnetization decreases. When the laminate thickness of each respective non-magnetic layer reaches 0.20 nm, the magnetization drops to about 570 emu/cm³ for Hf dopants, to about 310 emu/cm³ for Ti dopants, and about 95 emu/cm³ for Ta dopants.

FIG. 4B is a chart 410 illustrating a reduction in stray fields (H_{bias}) generated by the storage layer 12 on ferromagnetic sense layer 16 where the reduction in stray fields is caused by the reduction in magnetization from the various non-magnetic dopant materials according to an embodiment. The chart 410 shows the stray fields, H_{bias}, measured in oersted (Oe) on the y-axis and shows the laminate thickness of each non-magnetic layer in the multilayer storage layer 12. As can be seen, as the lamination thickness of each non-magnetic layer increases (which similar to increasing the percentage of non-magnetic material in the storage layer 12 as compared to the ferromagnetic material), the stray fields decrease.

In one case, the field line 80 may be a magnetic generating device 80 that is a combination of an (insulated) metal wire connected to a voltage source to generate the magnetic field as understood by one skilled in the art. Also, the magnetic generating device 80 may be a CMOS (complementary metal oxide semiconductor) circuit that generates the magnetic filed as understood by one skilled in the art.

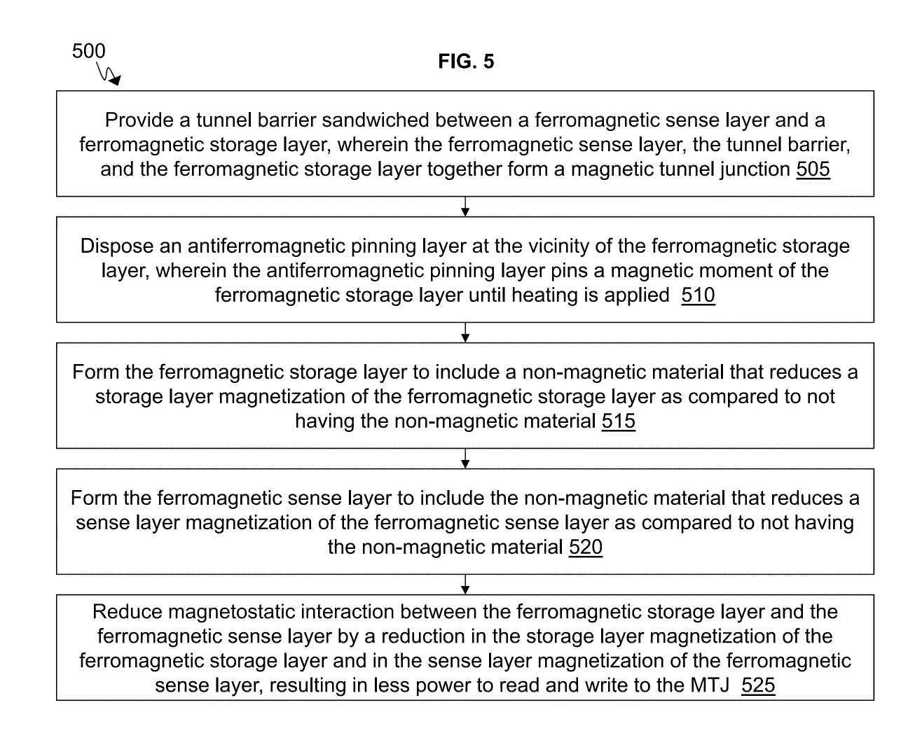

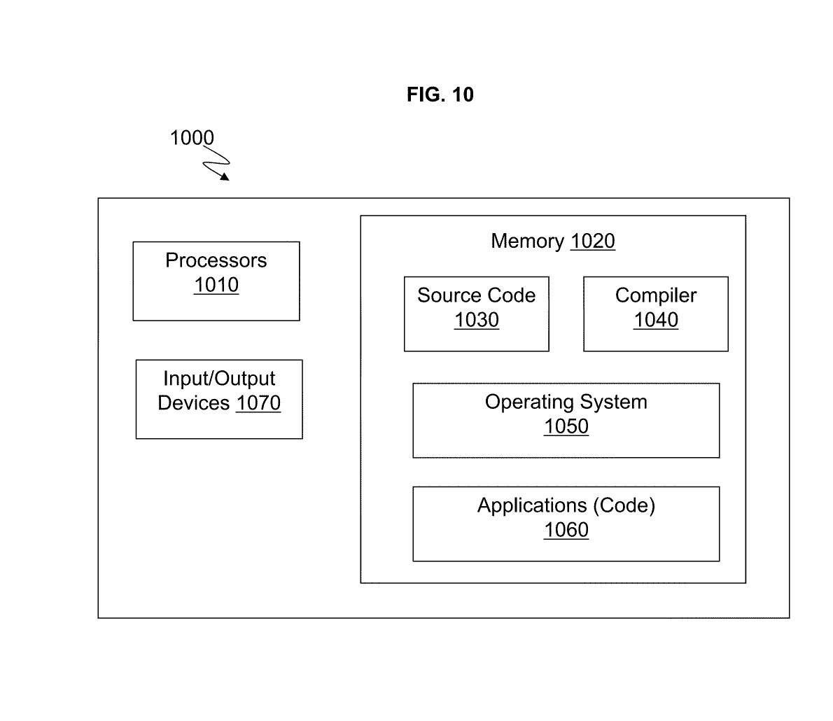

FIG. 5 illustrates a method 500 of reduced power for reading and writing the thermally assisted magnetoresistive random access memory device 100 according to an embodiment. Reference can be made to FIGS. 1-4 along with FIG. 10 discussed below.

At block 505, the tunnel barrier 14 is sandwiched between the ferromagnetic sense layer 16 and the ferromagnetic storage layer 12, in which the ferromagnetic sense layer 16, the tunnel barrier 14, and the ferromagnetic storage layer 12 together form the magnetic tunnel junction 10.

At block 510, the antiferromagnetic pinning layer 30 is disposed at an interface of the ferromagnetic storage layer 12, where the antiferromagnetic pinning layer 30 pins the magnetic moment of the ferromagnetic storage layer 12 until heating at the writing temperature is applied. The voltage source 70 applies current that causes heating in the tunnel barrier 14 to unpin the ferromagnetic storage layer 12 from the antiferromagnetic pinning layer 30. A write magnetic field is applied via the field line 80 to write (i.e., flip the magnetic moment) the ferromagnetic storage layer 12 when the ferromagnetic storage layer 12 is unpinned from the antiferromagnetic pinning layer 30.

At block 515, the ferromagnetic storage layer 12 is formed to include non-magnetic material (along with the ferromagnetic material) that reduces a storage layer magnetization (i.e., reduces the magnetic moment and stray fields) of the ferromagnetic storage layer 12 as compared to not having the non-magnetic material present in ferromagnetic storage layer 12.

At block 520, the ferromagnetic sense layer 16 is formed to include the non-magnetic material (along with the ferromagnetic material) that reduces the sense layer magnetization (i.e., reduces the magnetic moment and stray fields) of the ferromagnetic sense layer as compared to not having the non-magnetic material present in the ferromagnetic sense layer 16.

At block 525, the magnetostatic interaction between the ferromagnetic storage layer 12 and the ferromagnetic sense layer 16 are reduced by a reduction in the storage layer magnetization of the ferromagnetic storage layer 12 and a reduction in the sense layer magnetization of the ferromagnetic sense layer 16, resulting in less power to read and write to the magnetic tunnel junction 10. As such, the reduction in storage layer magnetization and sense layer magnetization require less power because a reduced magnitude write magnetic field and/or read magnetic field is required for the field line 80, which means less voltage and current are needed to generate the write/read magnetic field. Due to the reduction of magnetostatic interaction, the device 100 can be read and/or written with magnetic fields below 200 Oe, while it requires more than 250 Oe to read or write a conventional device (i.e. without the reduction of storage layer and sense layer magnetizations).

The ferromagnetic storage layer 12 and the ferromagnetic sense layer 16 respectively include dopants of the non-magnetic material (along with their ferromagnetic material) as discussed in FIG. 3.

The magnetic tunnel junction 10 and the antiferromagnetic pinning layer 30 to have a diameter less than 250 nanometers based upon the reduction in both the storage layer magnetization of the ferromagnetic storage layer 12 and the sense layer magnetization of the ferromagnetic sense layer 16. The reduction in both the storage layer magnetization of the ferromagnetic storage layer 12 and the sense layer magnetization of the ferromagnetic sense layer 16 reduce the magnetostatic interaction in order to allow reading and writing to the magnetic tunnel junction 10 that is less than 250 nanometers in diameter. Without the reduction in magnetization of layers 12 and 16, at a diameter less than 250 nanometers the stray magnetic fields from both the ferromagnetic storage layer 12 and the ferromagnetic sense layer 16 become so large (and the required magnitude of the write and read magnetic fields generated by the field line 80 would have to be extremely large) that it is not feasible to have a diameter less than 250 nanometers in a conventional system.

As an example, the magnetic tunnel junction 10 (i.e., layers 12, 14, and 16) and the antiferromagnetic pinning layer 30 are formed to have a diameter that is about 100 nanometers based upon the reduction in both the storage layer magnetization of the ferromagnetic storage layer 12 and the sense layer magnetization of the ferromagnetic sense layer 16. The reduction in both the storage layer magnetization of the ferromagnetic storage layer 12 and the sense layer magnetization of the ferromagnetic sense layer 16 reduce the stray magnetic fields in order to allow reading and writing to the magnetic tunnel junction that is about 100 nanometers in diameter.

The ferromagnetic storage layer 12 is formed by sputtering, chemical vapor deposition, and/or physical vapor deposition applied to a composite material having both ferromagnetic material and the non-magnetic material (target A plus B combined) as shown in FIG. 3A. The ferromagnetic storage layer 12 is formed from simultaneously co-sputtering a ferromagnetic material (target A) and the non-magnetic material (target B) as shown in FIG. 3B. As shown in FIG. 3C, the ferromagnetic storage layer 12 is formed of multilayers (i.e., the gray shaded layers and non-shaded layers) of the ferromagnetic material (target A) and the non-magnetic material (target B).

The ferromagnetic sense layer 16 is formed by sputtering, chemical vapor deposition, and/or physical vapor deposition applied to a composite material (targets A and B combined) having both ferromagnetic material and the non-magnetic material as shown in FIG. 3A. The ferromagnetic sense layer 16 is formed from simultaneously co-sputtering a ferromagnetic material (target A) and the non-magnetic material (target B). The ferromagnetic sense layer 16 is formed of multilayers (i.e., the gray shaded layers and non-shaded layers) of the ferromagnetic material (target A) and the non-magnetic material (target B) in FIG. 3C.

Ferromagnetic material is included in the first ferromagnetic storage layer, in the second ferromagnetic storage layer, and in the ferromagnetic sense layer. The ferromagnetic material includes Co, Fe, Ni and/or any alloy containing Co, Fe, and/or Ni. The non-magnetic material includes Ta, Ti, Hf, Cr, Nb, Mo, Zr, and/or any alloy containing Ta, Ti, Hf, Cr, Nb, Mo, and/or Zr. The non-magnetic material has a concentration between 1 and 40 atomic percent.

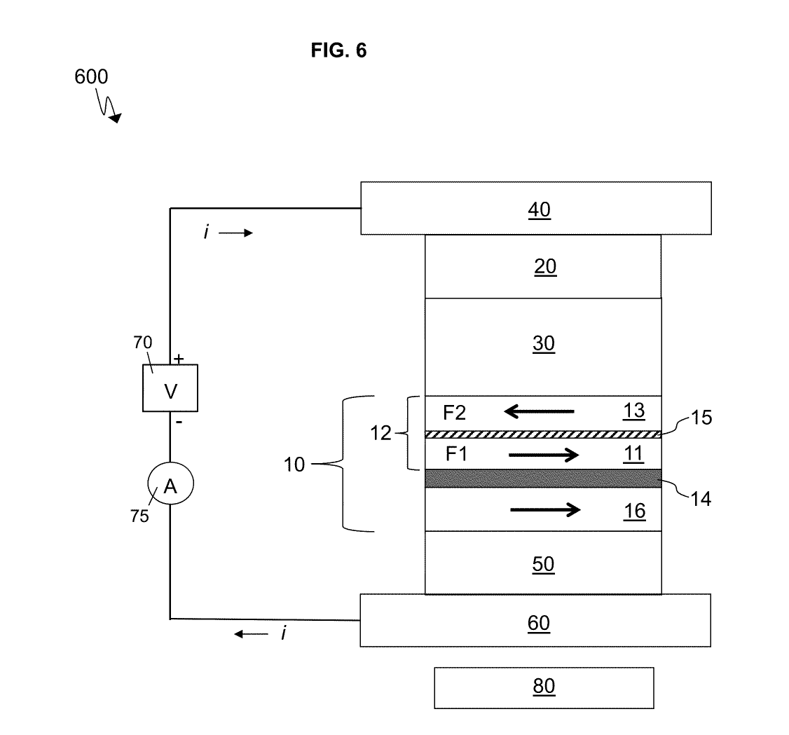

Now turning to FIG. 6, a cross-sectional view is illustrated of a structure for a thermally-assisted magnetoresistive random access memory (TAS-MRAM) device 600 according to an embodiment. FIG. 6 is similar FIG. 1 except that FIG. 6 shows the storage layer 12 as a synthetic antiferromagnet (SAF) storage layer 12.

The structure of the MRAM device 600 includes a magnetic tunnel junction (MTJ) 10. The magnetic tunnel junction 10 may include the ferromagnetic sense layer 16 with the non-magnetic tunnel barrier 14 disposed at an interface of the ferromagnetic sense layer 16. The magnetic tunnel junction 10 also includes the synthetic antiferromagnet (SAF) storage layer 12 disposed at an interface of the non-magnetic tunnel barrier 14. The non-magnetic tunnel barrier 14 may be a semiconductor or insulator. Although not shown, it is contemplated that the reverse configuration may also be provided for the magnetic tunnel junction 10 in which the sense layer 16 is deposited on top of the tunnel barrier 14, and the tunnel barrier 14 is deposited on top of the storage layer 12.

According to this embodiment of FIG. 6 in contrast to FIG. 1, the storage layer is the synthetic antiferromagnet storage layer 12, and the synthetic antiferromagnet storage layer 12 includes a first ferromagnetic layer 11 (also referred to as F1) disposed at an interface of the tunnel barrier layer 14. A non-magnetic coupling layer/material 15 is disposed at an interface of the ferromagnetic layer 11. A second ferromagnetic layer 13 (also referred to as F2) is disposed at an interface of the non-magnetic coupling layer 15. The second ferromagnetic layer 13 (F2), the non-magnetic coupling layer 15, and the first ferromagnetic layer 11 (F1) together form the synthetic antiferromagnet storage layer 12. The non-magnetic coupling layer 15 may be a Ru spacer. For a given Ru thickness as understood by one skilled in the art, the RKKY coupling through the Ru spacer is antiferromagnetic. Thus, the net magnetization of the synthetic antiferromagnet storage layer 12 is the difference of the F1 and F2 magnetic moments, which is the difference between the magnetic moment of second ferromagnetic layer 13 (F2) and the first ferromagnetic layer 11 (F1). The non-magnetic coupling layer 15 causes the magnetic moment of the second ferromagnetic layer 13 to be opposite to the magnetic moment of the first ferromagnetic layer 11. The magnetic moments of the second ferromagnetic layer 13 and the first ferromagnetic layer 11 both flip together. The magnetic moments are shown by arrows.

The antiferromagnetic (AF) pinning layer 30 is disposed at an interface of the synthetic antiferromagnet storage layer 12 and holds the magnetic moments of the second ferromagnetic layer 13 and the first ferromagnetic layer 11 in place until heating is applied by a write bias current. Particularly, antiferromagnetic (AF) pinning layer 30 is disposed at an interface of the second ferromagnetic layer 13 (F1). The antiferromagnetic pinning layer 30 is an antiferromagnet and may include materials such as, e.g., IrMn, FeMn, PtMn, etc. A discussed above, the antiferromagnetic pinning layer 30 is composed of two magnetic sublattices, which have opposite magnetic orientations (also referred to as magnetic moments), such that the net magnetic moment of the antiferromagnetic pinning layer 30 is zero. Since antiferromagnets have a small or no net magnetization, their spin orientation is only negligibly influenced by an externally applied magnetic field.

The contact structure 20 (non-magnetic cap) is disposed on top of the antiferromagnetic pinning layer 30 connecting the magnetic tunnel junction 10 (MRAM device 600) to the first wire 40. In the case of a reverse structure, the top contact structure 20 is deposited on top of the sense layer 16.

As noted earlier, the magnetic tunnel junction 10 (particularly the ferromagnetic sense layer 16) is disposed on top of the seed layer 50. However, in the reverse structure, the seed layer is disposed/lying below the antiferromagnet. In FIG. 6, the seed layer 50 is the seed for growing the ferromagnetic sense layer 16. Note that the seed layer 50 is optional, and in one implementation, the seed layer 50 may not be present. The seed layer 50, when present, is disposed on top of the second wire 60. When the seed layer 50 is not present, the ferromagnetic sense layer 16 is disposed on top of the second wire 60. The seed layer 50 is disposed on and/or connected to the second wire 60. Note, in the case of a reverse structure, the second wire 60 is disposed below the antiferromagnet 12. The wires 40 and 60 connect the MRAM device 600 to the voltage source 70 (for generating the write bias current to heat the MRAM device 600) and ammeter 75 for measuring current. As such, the resistance of the MTJ 10 (i.e., MRAM device 600) can be determined.

The first ferromagnetic layer 11 of the magnetic tunnel junction 10 can be used to store binary data. Indeed, the resistance of the magnetic tunnel junction 10 depends on the magnetic configuration (low resistance for parallel magnetizations, and high resistance for antiparallel magnetizations). The relative difference of resistance between the first ferromagnetic layer 11 in the synthetic antiferromagnet storage layer 12 and the ferromagnetic sense layer 16 is called tunnel magnetoresistance (TMR). Due to the hysteresis of the ferromagnetic layers (i.e., the synthetic antiferromagnet storage layer 12 and ferromagnetic sense layer 16), the magnetic tunnel junction 10 is used as a non-volatile cell. The reference layer presents high anisotropy, and cannot be switched under the functioning conditions of the device. The ferromagnetic layers 11 and 13 of the synthetic antiferromagnet storage layer 12 are stable under the stand-by conditions, but can be switched by an applied write/read magnetic field along with a write current sent through the junction.

The synthetic antiferromagnet storage layer 12 has exchange bias pinned ferromagnetic layers 11 and 13 which are pinned by the antiferromagnetic material of the antiferromagnetic pinning layer 30. The exchange bias acting on the synthetic antiferromagnet storage layer 12 can be overcome (in order to write to the synthetic antiferromagnet storage layer 12, i.e., flip the respective magnetic moments of ferromagnetic layers 11 and 13) by applying a current pulse (via the voltage source 70) through the stack (i.e., the MRAM device 600) that heats the junction (antiferromagnetic pinning layer 30) above its blocking temperature, in combination with the magnetic field (of the field line 80) that switches the now unpinned SAF storage layer 12. The magnetic moment of the second ferromagnetic layer 13 and first ferromagnetic layer 11 of the synthetic antiferromagnet storage layer 12 recover to their new pinning direction during cooling.

As an example of writing to the MRAM device 100, a write bias current (i) is generated from the voltage source 70, which travels through the MRAM device 600. Because of its high resistance, the tunnel barrier 14 heats up (as a result of Joule heating) when the write bias current flows through the tunnel barrier 14. The heat unpins the synthetic antiferromagnet storage layer 12 from the antiferromagnetic pinning layer 30. Since the synthetic antiferromagnet storage layer 12 is unpinned from the antiferromagnetic pinning layer 30, a magnetic write field is generated by the field line 80 to flip the magnetic moment of the ferromagnetic sense layer 16 and the magnetostatic interaction (i.e., stray fields) acting on the storage layer 12 flips the magnetic moment of the first ferromagnetic layer 11 (of the SAF storage layer 12). Accordingly, because of the non-magnetic coupling layer 15, the first ferromagnetic layer 11 reversal flips the second ferromagnetic layer 13 to have a magnetic orientation opposite of the magnetic orientation of the first ferromagnetic layer 11 (all while the heating is occurring). The write bias current is turned off to remove the heating. Accordingly, the magnetic moment of the first ferromagnetic layer 11 cools in place with its new direction, and the magnetic moment of the second ferromagnetic layer 13 cools in place with its new direction (opposite the first ferromagnetic layer 11). This is the process of storing data in the synthetic antiferromagnet storage layer 12.

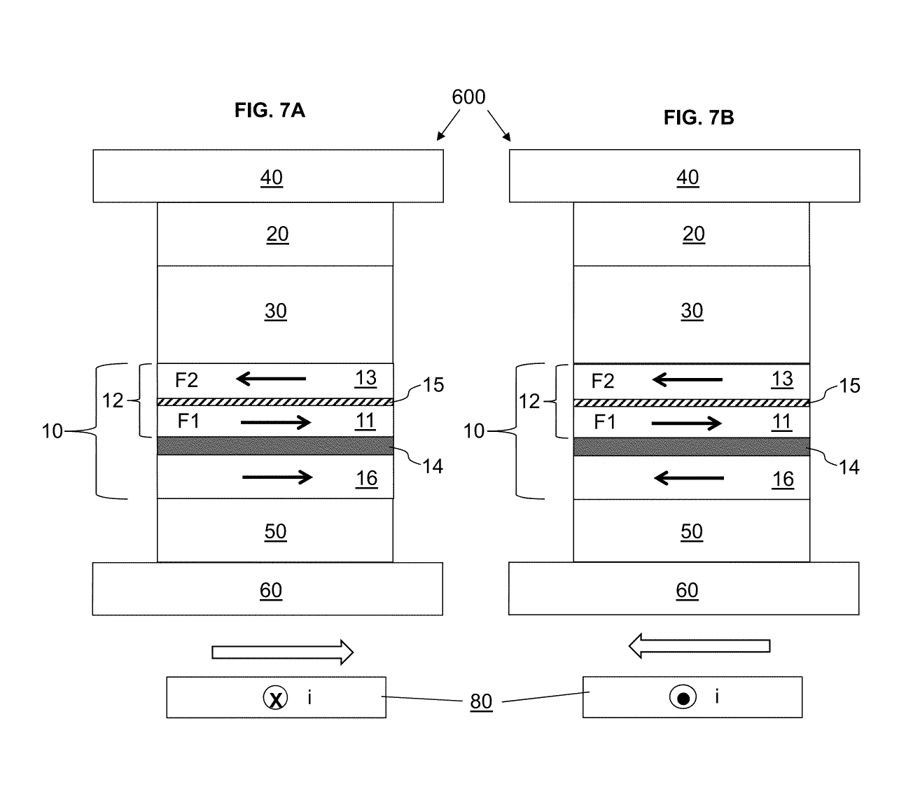

FIGS. 7A and 7B illustrate a reading procedure of the self-referenced magnetic tunnel junction 10 in the thermally-assisted magnetoresistive random access memory (TAS-MRAM) device 600 according to an embodiment.

During reading in FIG. 7A, the magnetic moment (shown by the solid arrow pointing to the right) of the ferromagnetic sense layer 16 is switched in one direction via bias current i (the “x” indicates that the current i is entering the plane of the page) applied in the field line 80 to generate a magnetic field shown by an open arrow pointing to the right. Note that the magnetic moment of the synthetic antiferromagnet storage layer 12 continues pointing in the same direction (i.e., the first ferromagnetic layer 11 continues pointing to the right while the second ferromagnetic layer 13 continues pointing to the left) and does not flip even when the magnetic field is applied via the field line 80. This is because the write bias current (i.e., heating) is not applied by the voltage source 70 to de-pin (unpin) the synthetic antiferromagnet storage layer 12 from the antiferromagnetic pinning layer 30.

While on the other hand in FIG. 7B, the magnetic moment (now shown by the solid arrow pointing to the left) of the ferromagnetic sense layer 16 is switched in the opposite direction via the current i (the dot “” indicates that the current i is exiting the plane of the page) applied in the field line 80 to generate the magnetic field shown by an open arrow pointing to the left. The write bias current is also not applied in FIG. 2B.

The difference in resistance between the two reading steps (i.e., between the magnetic moments of the ferromagnetic sense layer 16 pointing to the right and then left) can be either positive or negative, depending on the direction of the magnetic moments of the synthetic antiferromagnet storage layer 12. The sign of the resistance change yields the stored information in the first ferromagnetic layer 11 of the synthetic antiferromagnet storage layer 12. Note that the resistance of the MRAM device 600 is based on whether the first ferromagnetic layer 11 (F1) is parallel or antiparallel to the ferromagnetic sense layer 16. For example, when the magnetic moments of the first ferromagnetic layer 11 (of the SAF storage layer 12) and ferromagnetic sense layer 16 are parallel (i.e., pointing in the same direction) as shown in FIG. 7A, the resistance is low for the magnetic tunnel junction 10 (which represents a logical “1”). On the other hand, when the magnetic moments of the first ferromagnetic layer 11 (of the SAF storage layer 12) and ferromagnetic sense layer 16 are antiparallel (i.e., pointing in the opposite directions) as shown in FIG. 7B, the resistance is high for the magnetic tunnel junction 10 (which represents a logical “0”).

Normally, in a conventional stack, one would need to make the layers 11, 13, and 16 thin in order to tune the stray fields of the ferromagnetic sense layer 16 which flip the moment of the first ferromagnetic layer 11. The stray fields of the magnetization of the ferromagnetic sense layer 16 couple to the magnetization of the first ferromagnetic layer 11. However, embodiments use ferromagnetic layers doped with non-magnetic elements (i.e., in first and second ferromagnetic layers 11 and 13, in the storage layer 12, and in the ferromagnetic sense layer 16) in the self-referenced stack (of the thermally-assisted magnetoresistive random access memory (TAS-MRAM) device 600) that present a magnetization reduction as compared to the standard ferromagnetic materials that do not have the reduced magnetization for thermally-assisted magnetoresistive random access memory (TAS-MRAM) device.

By having the reduced magnetization, the layers 11, 13, and 16 can be made thicker than in the conventional system without the reduced magnetization. In the conventional system without doping to reduce magnetization, the thickness of the ferromagnetic sense layer 16 is typically 20-30 Angstroms (Å), the thickness of the second ferromagnetic layer 13 is typically 15-30 Å, and the thickness of first ferromagnetic layer 11 is typically 15-30 Å. As understood by one skilled in the art, the accuracy of the deposition of the thin layers 11, 13, and 16 in the conventional system is more difficult than for thicker layers in embodiments.

According to embodiments with the reduced magnetization, the thickness of the ferromagnetic sense layer 16 may be 10-60 (Å), e.g., the ferromagnetic sense layer 16 may be (about) 10 . . . 35, 40, 45, 50, 55, 60 Å thick (or more). With the reduced magnetization, the thickness of the second ferromagnetic layer 13 may be 10-60 Å, e.g., the second ferromagnetic layer 13 may be (about) 10 . . . 35, 40, 50, 55, 60 Å thick (or more). Also, with the reduced magnetization, the thickness of first ferromagnetic layer 11 may be 10-60 Å, e.g., the first ferromagnetic layer 11 may be (about) 35, 40, 50, 55, 60 Å thick (or more). Additionally, the accuracy of deposition is increased when depositing material at a thickness of 60 Å for the ferromagnetic sense layer 16, 60 Å for the second ferromagnetic layer 13, and 60 Å for the first ferromagnetic layer 11 as compared to the thinner deposition layers in conventional systems (discussed herein).

Also, if one tried to make the thick layers 11, 13, and 16 (as discussed above for embodiments for the thicker deposition of materials) while using the conventional system without the reduced magnetizations, the stray magnetic dispersion among the pillars for layers 11, 13, and 16 would be too large. For the conventional system, assuming a thickness dispersion of about 3% and a magnetization above 1200 emu/cm³ makes the stray field dispersion among pillars too large when the first and/or second ferromagnetic thickness exceeds 30 Å (in thickness). Using ferromagnetic layers with reduced magnetization allows one to make a thicker layer, proportionally to the magnetization reduction, (since the magnetic moment is the product of the magnetization with the magnetic volume) according to embodiments. For example, a reduction by a factor of two of the magnetization of the first and second layers allows making up to 60 Å thick first and second ferromagnetic layers.

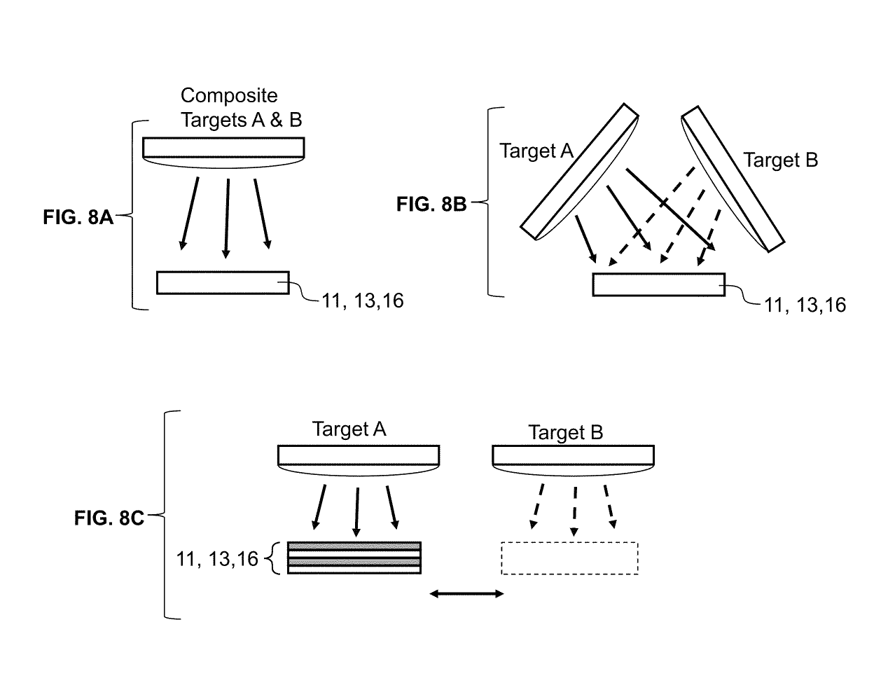

To make the second ferromagnetic layer 13 and first ferromagnetic layer 11 in synthetic antiferromagnet storage layer 12 and the ferromagnetic sense layer 16 with reduced magnetizations (i.e., reduced magnetic moments in each), FIGS. 8A, 8B, and 8C (generally referred to as FIG. 8) illustrate doping the ferromagnetic layers 11 and 13 of the synthetic antiferromagnetic storage layer 12 and the ferromagnetic sense layer 16 to reduce magnetization according to an embodiment. Note that such a doped ferromagnetic layer can be made by sputtering from an alloyed target, by co-sputtering from several targets, and/or by making a multilayer that consists of alternating ferromagnetic and non-magnetic thin layers. Also note that the description of FIG. 8 applies separately to each of the layers 11, 13, and 16. Some details in FIG. 8 may be similar to FIG. 3.

In order to reduce the magnetic moment of the second ferromagnetic layer (F2) magnetization, first ferromagnetic layer (F1) magnetization, and sense layer magnetization, non-magnetic materials can be used to dope the ferromagnetic layers. As discussed above, the ferromagnetic materials include a Co, Fe, and/or Ni based alloy, while the non-magnetic doping elements can be Ta, Ti, Hf, Cr, Nb, Mo, Zr, and/or any alloy containing one of these elements. The first ferromagnetic layer 11 has a doped ferromagnetic layer in order to have a magnetization that is (typically) below 1000 emu/cm³, where emu is electromagnetic unit. Likewise, the second ferromagnetic layer 13 has the doped ferromagnetic layer in order to have a magnetization that is (typically) below 1000 emu/cm³. The doped ferromagnetic layer of the ferromagnetic sense layer 16 also has a magnetization that is (typically) below 1000 emu/cm³. This reduced magnetization in the ferromagnetic layers 11 and 13 in the synthetic antiferromagnet storage layer 12 and ferromagnetic sense layer 16 reduces the magnetostatic interaction between the first ferromagnetic layers 11 and the ferromagnetic sense layer 16 and between the second ferromagnetic layer 13 and the ferromagnetic sense layer 16. As noted above, reducing magnetization in the layers 11, 13, and 16 (to reduce the stray fields) is what permits a proper write field dispersion among the pillars in the memory device in embodiments.

When there is no doping of the ferromagnetic layers in the SAF storage layer and ferromagnetic sense layer (i.e., their magnetization is not reduced), a conventional system has a first ferromagnetic layer (F1) and second ferromagnetic layer each with a conventional magnetization of 1000 to 1700 emu/cm³. A conventional system has a sense layer with a conventional magnetization of 1000 to 1700 emu/cm³

The (magnetic moments of F1 and F2) synthetic antiferromagnetic storage layer 12 is pinned with a Mn based antiferromagnet in antiferromagnetic pinning layer 30, and the antiferromagnetic pinning layer 30 may be PtMn, IrMn, IrCrMn, and/or FeMn.

FIG. 8 illustrates three example techniques to deposit the doped ferromagnetic layers for the first ferromagnetic layer 11, the second ferromagnetic layer 13, and/or the ferromagnetic sense layer 16, which are part of the stack in the thermally-assisted magnetoresistive random access memory device 600 discussed herein. FIG. 8A shows depositing an alloy by sputtering from a composite target A plus B made of the desired alloy to form the desired storage layer 12 and/or ferromagnetic sense layer 16 with reduced magnetization. The material A is the ferromagnetic material (i.e., magnetic material discussed herein) and the target B is the non-magnetic material (discussed herein). The targets A plus B have been made into an alloy in FIG. 8A for deposition to form the desired the first ferromagnetic layer 11, the second ferromagnetic layer 13, and/or ferromagnetic sense layer 16.

FIG. 8B shows depositing the alloy by co-sputtering from different targets A and B containing the desired magnetic and non-magnetic elements to form the desired the first ferromagnetic layer 11, the second ferromagnetic layer 13, and/or ferromagnetic sense layer 16 with reduced magnetization. The target A is the ferromagnetic material (i.e., magnetic material) and the target B is the non-magnetic material. The doped ferromagnetic layers of the first ferromagnetic layer 11, the second ferromagnetic layer 13, and/or ferromagnetic sense layer 16 respectively are formed by co-sputtering from the separate target A and separate target B.

FIG. 8C shows depositing a multilayered stack comprising ferromagnetic and non-magnetic bilayers with n repetitions, where n ranges from 1 to 20. Again, the target A is the ferromagnetic material (i.e., magnetic material) and the target B is the non-magnetic material. For example, sputtering from target A is performed to deposit a ferromagnetic layer of the first ferromagnetic layer 11, the second ferromagnetic layer 13, and/or ferromagnetic sense layer 16, and then layer 11, 13, and/or 16 is shifted under the target B in order to perform sputtering from target B to deposit the non-magnetic layer on top of the previously deposited ferromagnetic layer (i.e., thus forming the first bilayer). Next, the layer 11, 13, and/or 16 is shifted back under target A to deposit another ferromagnetic layer on top of the non-magnetic layer, and then the layer 11, 13, and/or 16 is shifted under the target B in order to deposit the non-magnetic layer on top of the ferromagnetic layer. This process repeats for n repetitions. The thickness of each deposited ferromagnetic layer of the ferromagnetic material (FM) is between 0.1 to 2 nm while thickness of the non-magnetic material (NM) is below 1 nm.

In FIG. 8, the doped ferromagnetic layers (i.e., ferromagnetic layers doped with non-magnetic material) can present a gradient of doping. This gradient can be made by varying the sputtering conditions (pressure, flow, power, etc.) during the doped layer deposition, and/or by varying the relative thicknesses of ferromagnetic layer and non-magnetic material layer in the multilayer case. In the multilayer case, the multilayer stack comprises FM1/NM1/ . . . /FMn/NMn, where FMk and NMk denote ferromagnetic and non-magnetic materials of different nature and thickness.

The ferromagnetic layers' doping is designed to be compatible with these characteristics: TMR ratio above 10%, MTJ resistance-area product below 100 Ohm·μm², and exchange bias field of the second ferromagnetic layer of the storage layer above 200 Oe at room temperature.

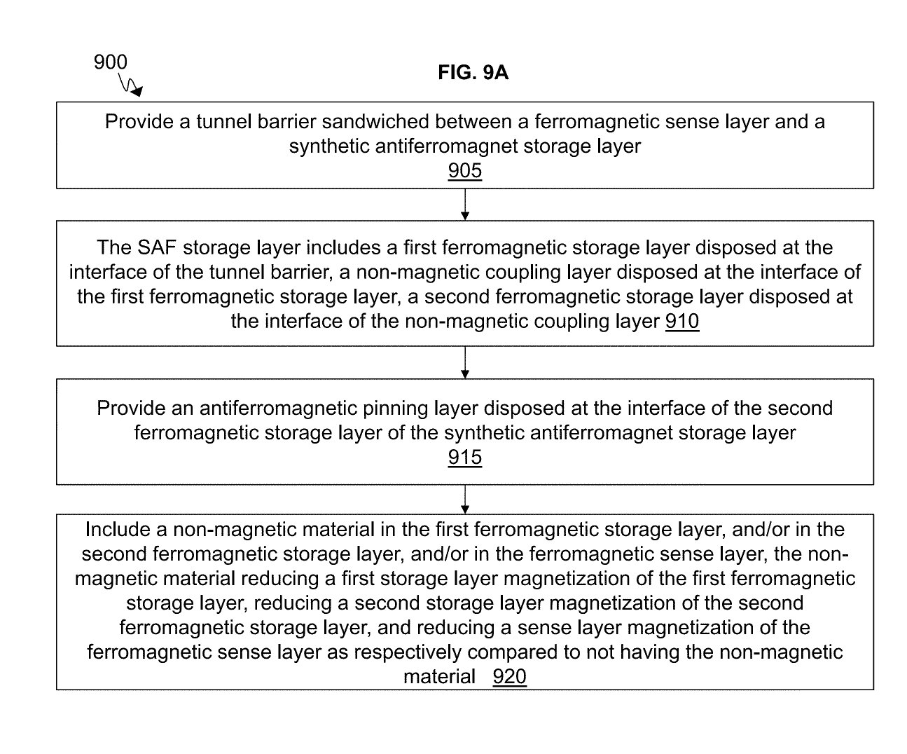

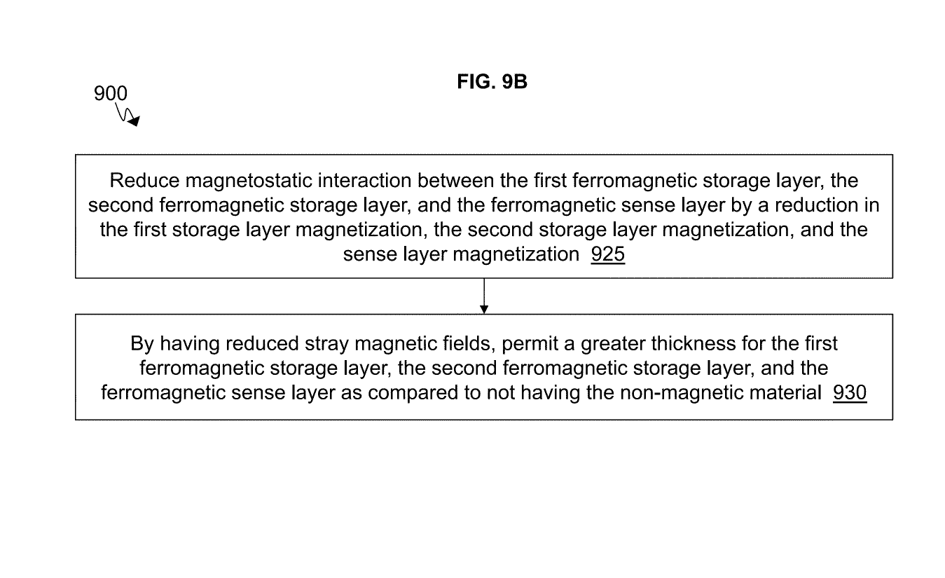

FIGS. 9A and 9B illustrate a method 900 of reduced power for reading and writing the thermally assisted magnetoresistive random access memory device 600 according to an embodiment. FIGS. 9A and 9B may generally be referred to as FIG. 9. Reference can be made to FIGS. 4 and 6-8 along with FIG. 10 discussed below.

At block 905, the tunnel barrier 14 is sandwiched between the ferromagnetic sense layer 16 and the synthetic antiferromagnet storage layer 12.

At block 910, the synthetic antiferromagnet storage layer 12 is disposed at an interface of the tunnel barrier 14, where the synthetic antiferromagnet storage layer 12 includes the first ferromagnetic storage layer 11 disposed at an interface of the tunnel barrier 14, the non-magnetic coupling layer 15 disposed at the other interface of the first ferromagnetic storage layer 11, and the second ferromagnetic storage layer 13 disposed at the other interface of the non-magnetic coupling layer 15.

At block 915, the antiferromagnetic pinning layer 30 is disposed at an interface of the ferromagnetic storage layer 13 of the synthetic antiferromagnet storage layer 12. The antiferromagnetic pinning layer 30 pins the (opposite pointing) magnetic moments of the ferromagnetic storage layer 11 and 13 until heating is applied. The voltage source 70 applies current that causes heating in the tunnel barrier 14 to unpin the ferromagnetic storage layer 11 and 13 from the antiferromagnetic pinning layer 30. A write magnetic field is applied via the field line 80 to write (i.e., flip the magnetic moment) the first ferromagnetic storage layer 11 via stray fields from the ferromagnetic sense layer 16 when the first ferromagnetic storage layer 11 is unpinned from the antiferromagnetic pinning layer 30. As such, the non-magnetic coupling layer 15 then flips the second ferromagnetic storage layer 13 accordingly to maintain a magnetic moment opposite the first ferromagnetic storage layer 11.

At block 920, the first ferromagnetic storage layer 11, the second ferromagnetic storage layer 13, and the ferromagnetic sense layer 16 are each formed of ferromagnetic material (which may be the same or different ferromagnetic material) (along with the ferromagnetic material), in which a non-magnetic material reduces a first storage layer magnetization (i.e., reduces the magnetic moment and stray fields dispersions) of the first ferromagnetic storage layer 11, reduces a second storage layer magnetization (i.e., reduces the magnetic moment and stray fields dispersions) of the second ferromagnetic storage layer 13, and reduces a sense layer magnetization (i.e., reduces the magnetic moment and stray fields dispersions) of the ferromagnetic sense layer 16 as respectively compared to not having the non-magnetic material present in layers 11, 13, 16.

At block 925, the magnetostatic interaction between the first ferromagnetic storage layer 11, the second ferromagnetic storage layer 13, and the ferromagnetic sense layer 16 are reduced by a reduction in the first storage layer magnetization of the ferromagnetic storage layer 11, a reduction in the second storage layer magnetization of the ferromagnetic storage layer 13, and a reduction in the sense layer magnetization of the ferromagnetic sense layer 16, resulting in less stray fields dispersions among pillars and thus in less power to read and write to the SAF storage layer 12 in the magnetic tunnel junction 10. As such, the reduction in first storage layer magnetization, second storage magnetization, and sense layer magnetization require less power because a reduced magnitude write magnetic field and/or read magnetic field is needed for the field line 80, which means less voltage and current are needed to generate the write/read magnetic field. As a result of the reduction of magnetostatic interaction dispersion, the device 600 can be read or written with magnetic fields below 200 Oe, while it requires more than 250 Oe to read or write a conventional device (i.e. without the reduction of storage layer and sense layer magnetization).

By having reduced magnetization, a greater thickness is permitted (or functions) for the first ferromagnetic storage layer, the second ferromagnetic storage layer, and the ferromagnetic sense layer as compared to not having the non-magnetic material at block 930.

The first ferromagnetic storage layer 11, second ferromagnetic storage layer 13, and the ferromagnetic sense layer 16 respectively include dopants of the non-magnetic material (along with their ferromagnetic material) as discussed in FIG. 8.

The antiferromagnetic pinning layer, the synthetic antiferromagnet storage layer, the tunnel barrier, and the ferromagnetic sense layer each have a diameter less than 100 nanometers based upon the reduction in the first storage layer magnetization of the first ferromagnetic storage layer 11, second storage layer magnetization of the second ferromagnetic storage layer 13, and the sense layer magnetization of the ferromagnetic sense layer 16. The reduction in the first storage layer magnetization of the first ferromagnetic storage layer 11, second storage layer magnetization of the second ferromagnetic storage layer 13, and the sense layer magnetization of the ferromagnetic sense layer 16 reduce the stray magnetic field dispersions in order to allow reading and writing to the SAF storage layer 12 that is less than 100 nanometers in diameter. Without the reduction in magnetization of layers 11, 13, and 16, at a diameter less than 100 nanometers the stray magnetic fields dispersion from layers 11, 13, and 16 become so large (and the required magnitude of the write and read magnetic fields generated by the field line 80 would have to be extremely large) that it is not feasible to have a diameter less than 100 nanometers in a conventional system.

Also, the antiferromagnetic pinning layer 30, the synthetic antiferromagnet storage layer 12, the tunnel barrier 14, and the ferromagnetic sense layer 16 may each have a diameter that is about 100 nanometers based upon the reduction in the first storage layer magnetization of the first ferromagnetic storage layer, the reduction in the second storage layer magnetization of the second ferromagnetic storage layer, and the reduction in the sense layer magnetization of the ferromagnetic sense layer.

The first ferromagnetic storage layer, the second ferromagnetic storage layer, and the ferromagnetic sense layer are formed by sputtering, chemical vapor deposition, and/or physical vapor deposition applied to a composite material having both ferromagnetic material and the non-magnetic material (target A and B combined) as shown in FIG. 8A. The first ferromagnetic storage layer, the second ferromagnetic storage layer, and the ferromagnetic sense layer are formed from simultaneously co-sputtering a ferromagnetic material (target A) and the non-magnetic material (target B) as shown in FIG. 8B. As shown in FIG. 8C, the first ferromagnetic storage layer, the second ferromagnetic storage layer, and the ferromagnetic sense layer are formed of multilayers (i.e., the gray shaded layers and non-shaded layers) of the ferromagnetic material (target A) and the non-magnetic material (target B).

A thickness of the first ferromagnetic storage layer is 10-60 Angstroms (Å), a thickness of the second ferromagnetic storage layer is 10-60 Å, and a thickness of the ferromagnetic sense layer is 10-60 Å.

The ferromagnetic material is included in the first ferromagnetic storage layer, in the second ferromagnetic storage layer, and in the ferromagnetic sense layer. The ferromagnetic material includes Co, Fe, Ni and/or any alloy containing Co, Fe, and Ni. The non-magnetic material includes Ta, Ti, Hf, Cr, Nb, Mo, Zr, and/or any alloy containing Ta, Ti, Hf, Cr, Nb, Mo, Zr. The non-magnetic material has a concentration between 1 and 40 atomic percent.

FIG. 10 illustrates an example of a computer 1000 which includes the MRAM devices 100, 600 having the reduction in magnetization in layers 12 and 16 (along with the reduction in power requirements for the read and write magnetic fields discussed herein). The computer 1000 has capabilities that may be included in exemplary embodiments. The MRAM devices 100, 600 may be constructed in a memory array, e.g., multiple MRAM devices 100, 600 connected together as understood by one skilled in the art (for reading and writing data), and the memory array may be part of the computer memory 1020 discussed herein. Various methods, procedures, circuits, elements, and techniques discussed herein may also incorporate and/or utilize the capabilities of the computer 1000. One or more of the capabilities of the computer 1000 may be utilized to implement, to incorporate, to connect to, and/or to support any element discussed herein (as understood by one skilled in the art) in FIGS. 1-9.

Generally, in terms of hardware architecture, the computer 1000 may include one or more processors 1010, computer readable storage memory 1020, and one or more input and/or output (I/O) devices 1070 that are communicatively coupled via a local interface (not shown). The local interface can be, for example but not limited to, one or more buses or other wired or wireless connections, as is known in the art. The local interface may have additional elements, such as controllers, buffers (caches), drivers, repeaters, and receivers, to enable communications. Further, the local interface may include address, control, and/or data connections to enable appropriate communications among the aforementioned components.

The processor 1010 is a hardware device for executing software that can be stored in the memory 1020. The processor 1010 can be virtually any custom made or commercially available processor, a central processing unit (CPU), a data signal processor (DSP), or an auxiliary processor among several processors associated with the computer 1000, and the processor 1010 may be a semiconductor based microprocessor (in the form of a microchip) or a microprocessor.

The computer readable memory 1020 can include any one or combination of volatile memory elements (e.g., random access memory (RAM), such as dynamic random access memory (DRAM), static random access memory (SRAM), etc.) and nonvolatile memory elements (e.g., ROM, erasable programmable read only memory (EPROM), electronically erasable programmable read only memory (EEPROM), programmable read only memory (PROM), tape, compact disc read only memory (CD-ROM), disk, diskette, cartridge, cassette or the like, etc.). Moreover, the memory 1020 may incorporate electronic, magnetic, optical, and/or other types of storage media. Note that the memory 1020 can have a distributed architecture, where various components are situated remote from one another, but can be accessed by the processor 1010.

The software in the computer readable memory 1020 may include one or more separate programs, each of which comprises an ordered listing of executable instructions for implementing logical functions. The software in the memory 1020 includes a suitable operating system (O/S) 1050, compiler 1040, source code 1030, and one or more applications 1060 of the exemplary embodiments. As illustrated, the application 1060 comprises numerous functional components for implementing the features, processes, methods, functions, and operations of the exemplary embodiments. The application 1060 of the computer 1000 may represent numerous applications, agents, software components, modules, interfaces, controllers, etc., as discussed herein but the application 1060 is not meant to be a limitation.

The operating system 1050 may control the execution of other computer programs, and provides scheduling, input-output control, file and data management, memory management, and communication control and related services.

The application 1060 may be a source program, executable program (object code), script, or any other entity comprising a set of instructions to be performed. When a source program, then the program is usually translated via a compiler (such as the compiler 1040), assembler, interpreter, or the like, which may or may not be included within the memory 1020, so as to operate properly in connection with the O/S 1050. Furthermore, the application 1060 can be written as (a) an object oriented programming language, which has classes of data and methods, or (b) a procedure programming language, which has routines, subroutines, and/or functions.

The I/O devices 1070 may include input devices (or peripherals) such as, for example but not limited to, a mouse, keyboard, scanner, microphone, camera, etc. Furthermore, the I/O devices 1070 may also include output devices (or peripherals), for example but not limited to, a printer, display, etc. Finally, the I/O devices 1070 may further include devices that communicate both inputs and outputs, for instance but not limited to, a NIC or modulator/demodulator (for accessing remote devices, other files, devices, systems, or a network), a radio frequency (RF) or other transceiver, a telephonic interface, a bridge, a router, etc. The I/O devices 1070 also include components for communicating over various networks, such as the Internet or an intranet. The I/O devices 1070 may be connected to and/or communicate with the processor 1010 utilizing Bluetooth connections and cables (via, e.g., Universal Serial Bus (USB) ports, serial ports, parallel ports, FireWire, HDMI (High-Definition Multimedia Interface), etc.).

When the computer 1000 is in operation, the processor 1010 is configured to execute software stored within the memory 1020, to communicate data to and from the memory 1020, and to generally control operations of the computer 1000 pursuant to the software. The application 1060 and the O/S 1050 are read, in whole or in part, by the processor 1010, perhaps buffered within the processor 1010, and then executed.

When the application 1060 is implemented in software it should be noted that the application 1060 can be stored on virtually any computer readable storage medium for use by or in connection with any computer related system or method.

The application 1060 can be embodied in any computer-readable medium for use by or in connection with an instruction execution system, apparatus, server, or device, such as a computer-based system, processor-containing system, or other system that can fetch the instructions from the instruction execution system, apparatus, or device and execute the instructions.

In exemplary embodiments, where the application 1060 is implemented in hardware, the application 1060 can be implemented with any one or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A thermally assisted magnetoresistive random access memory device (TAS-MRAM) with reduced power for reading and writing, the device comprising:
a tunnel barrier disposed adjacent to a ferromagnetic sense layer and a ferromagnetic storage layer, such that the tunnel barrier is sandwiched between the ferromagnetic sense layer and the ferromagnetic storage layer, wherein the ferromagnetic sense layer, the tunnel barrier, and the ferromagnetic storage layer together form a magnetic tunnel junction; and
an antiferromagnetic pinning layer disposed adjacent to the ferromagnetic storage layer;
wherein the antiferromagnetic pinning layer pins a magnetic moment of the ferromagnetic storage layer until heating is applied;
wherein at least one of:
the ferromagnetic storage layer includes a non-magnetic material to reduce a storage layer magnetization of the ferromagnetic storage layer as compared to not having the non-magnetic material; and
the ferromagnetic sense layer includes the non-magnetic material to reduce a sense layer magnetization of the ferromagnetic sense layer as compared to not having the non-magnetic material; and
wherein a reduction at least one of in the storage layer magnetization of the ferromagnetic storage layer and in the sense layer magnetization of the ferromagnetic sense layer reduces magneto static interaction between the ferromagnetic storage layer and the ferromagnetic sense layer, resulting in less power to read and write the magnetic tunnel junction as compared to the ferromagnetic storage layer and the ferromagnetic sense layer not having the non-magnetic material.

2. The device of claim 1, wherein the ferromagnetic storage layer and the ferromagnetic sense layer include dopants of the non-magnetic material.

3. The device of claim 1, wherein the magnetic tunnel junction and the antiferromagnetic pinning layer have a diameter less than 250 nanometers based upon the reduction in at least on of the storage layer magnetization of the ferromagnetic storage layer and the sense layer magnetization of the ferromagnetic sense layer; and
wherein the reduction in at least one of the storage layer magnetization of the ferromagnetic storage layer and the sense layer magnetization of the ferromagnetic sense layer reduce stray magnetic fields in order to allow reading and writing to the magnetic tunnel junction that is less than 250 nanometers in the diameter.

4. The device of claim 1, wherein the ferromagnetic storage layer is formed by sputtering, chemical vapor deposition, or physical vapor deposition applied to a composite material having both ferromagnetic material and the non-magnetic material.

5. The device of claim 1, wherein the ferromagnetic storage layer is formed from simultaneously co-sputtering a ferromagnetic material and the non-magnetic material.

6. The device of claim 1, wherein the ferromagnetic storage layer is formed of multilayers of a ferromagnetic material and the non-magnetic material.

7. The device of claim 1, wherein the ferromagnetic sense layer is formed by sputtering, chemical vapor deposition, or physical vapor deposition applied to a composite material having both ferromagnetic material and the non-magnetic material.

8. The device of claim 1, wherein the ferromagnetic sense layer is formed from simultaneously co-sputtering a ferromagnetic material and the non-magnetic material.

9. The device of claim 1, wherein the ferromagnetic sense layer is formed of multilayers of a ferromagnetic material and the non-magnetic material.

10. The device of claim 1, wherein a ferromagnetic material is included in the ferromagnetic storage layer and in the ferromagnetic sense layer;
wherein the ferromagnetic material includes at least one of Co, Fe, Ni and any alloy containing at least one of Co, Fe, and Ni; and
wherein the non-magnetic material includes at least one of Ta, Ti, Hf, Cr, Nb, Mo, Zr, and any alloy containing at least one of Ta, Ti, Hf, Cr, Nb, Mo, and Zr.

11. A thermally assisted magnetoresistive random access memory device (TAS-MRAM) with reduced power for reading and writing, the device comprising:
a tunnel barrier disposed adjacent to a ferromagnetic sense layer and a synthetic antiferromagnet storage layer, such that the tunnel barrier is sandwiched between the ferromagnetic sense layer and the synthetic antiferromagnet storage layer, wherein the synthetic antiferromagnet storage layer includes a first ferromagnetic storage layer disposed adjacent to the tunnel barrier, and a non-magnetic coupling layer sandwiched between the first ferromagnetic storage layer and a second ferromagnetic storage layer;
an antiferromagnetic pinning layer disposed adjacent to the second ferromagnetic storage layer of the synthetic antiferromagnet storage layer but opposite the non-magnetic coupling layer; and
a non-magnetic material included at least one of in the first ferromagnetic storage layer, in the second ferromagnetic storage layer, and in the ferromagnetic sense layer, the non-magnetic material reducing a first storage layer magnetization of the first ferromagnetic storage layer, reducing a second storage layer magnetization of the second ferromagnetic storage layer, and reducing a sense layer magnetization of the ferromagnetic sense layer as respectively compared to not having the non-magnetic material;
wherein a reduction in the first storage layer magnetization, the second storage layer magnetization, and the sense layer magnetization reduces magneto static interaction dispersions between the first ferromagnetic storage layer, the second ferromagnetic storage layer, and the ferromagnetic sense layer, resulting in less power to read and write as compared to the first ferromagnetic storage layer, the second ferromagnetic storage layer, and the ferromagnetic sense layer not having the non-magnetic material; and
wherein reduced magnetization permit a greater thickness for the first ferromagnetic storage layer, the second ferromagnetic storage layer, and the ferromagnetic sense layer as compared to not having the non-magnetic material.

12. The device of claim 11, wherein the first ferromagnetic storage layer, the second ferromagnetic storage layer, and the ferromagnetic sense layer each include dopants of the non-magnetic material.

13. The device of claim 11, wherein the antiferromagnetic pinning layer, the synthetic antiferromagnet storage layer, the tunnel barrier, and the ferromagnetic sense layer each have a diameter less than 100 nanometers based upon the reduction in the first storage layer magnetization of the first ferromagnetic storage layer, the reduction in the second storage layer magnetization of the second ferromagnetic storage layer, and the reduction in the sense layer magnetization of the ferromagnetic sense layer.

14. The device of claim 13, wherein the reduction in the first storage layer magnetization of the first ferromagnetic storage layer, the second storage layer magnetization of the second ferromagnetic storage layer, and the sense layer magnetization of the ferromagnetic sense layer reduce stray magnetic field dispersions in order to allow reading and writing to the synthetic antiferromagnet storage layer that is less than 100 nanometers in diameter.

15. The device of claim 11, wherein the first ferromagnetic storage layer, the second ferromagnetic storage layer, and the ferromagnetic sense layer are formed by sputtering, chemical vapor deposition, or physical vapor deposition applied to a composite material having both ferromagnetic material and the non-magnetic material.

16. The device of claim 11, wherein the first ferromagnetic storage layer, the second ferromagnetic storage layer, and the ferromagnetic sense layer are each formed by simultaneously co-sputtering a ferromagnetic material and the non-magnetic material.

17. The device of claim 11, wherein the first ferromagnetic storage layer, the second ferromagnetic storage layer, and the ferromagnetic sense layer are each formed of multilayers of a ferromagnetic material and the non-magnetic material.

18. The device of claim 11, wherein a ferromagnetic material is included in the first ferromagnetic storage layer, in the second ferromagnetic storage layer, and in the ferromagnetic sense layer; and
wherein the ferromagnetic material includes at least one of Co, Fe, Ni and any alloy containing at least one of Co, Fe, and Ni.

19. The device of claim 11, wherein the non-magnetic material includes Ta, Ti, Hf, Cr, Nb, Mo, Zr, and any alloy containing at least one of Ta, Ti, Hf, Cr, Nb, Mo, Zr.

20. The device of claim 11, wherein the non-magnetic material has a concentration between 1 and 40 atomic percent; and
wherein a thickness of the first ferromagnetic storage layer is 10-60 Angstroms (Å), a thickness of the second ferromagnetic storage layer is 10-60 Å, and a thickness of the ferromagnetic sense layer is 10-60 Å.
